(19) United States
(12) Patent Application Publication
(10) Pub. No.: US 2005/0214459 A1
(43) Pub. Date: Sep. 29, 2005

(54) Diamond and aggregated carbon fiber and production methods

(75) Inventors: Teigo Sakakibara, Yokohama-shi (JP); Yoichi Hirose, Atsugi-shi (JP)

Correspondence Address: FITZPATRICK CELLA HARPER & SCINTO, 30 ROCKEFELLER PLAZA, NEW YORK, NY, 10112, US

(73) Assignees: CANON KABUSHIKI KAISHA, Tokyo (JP); TOKAI UNIVERSITY EDUCATIONAL SYSTEM, Tokyo (JP)

(21) Appl. No.: 11/081,559

(22) Filed: Mar. 17, 2005

(30) Foreign Application Priority Data
Mar. 25, 2004 (JP) 2004-089533(PAT.)

(51) Int. Cl. C23C 16/00; B32B 9/00

(52) U.S. Cl. 427/249.1; 428/408

(57) ABSTRACT

An object of the present invention is to provide methods of easily producing a diamond and an aggregated carbon fiber. The methods of the present invention are methods of producing a diamond and an aggregated carbon fiber used by heat treatment vapor of a carbon source in the absence of air, the methods including the following steps (i) and (iii) of, the following steps (ii) and (iii) of, or the following steps (i), (ii) and (iii) of: (i) heating a liquid containing at least carbon, oxygen and hydrogen as components in a vessel from an outside of the vessel to exhaust air in the vessel by means of vapor of the liquid; (ii) introducing a gas into a vessel storing the liquid containing at least carbon, oxygen and hydrogen as components to exhaust air in the vessel; and (iii) heating the vapor of the liquid containing at least carbon, oxygen and hydrogen as components in an atmosphere of the saturated vapor of the liquid.

### BACKGROUND OF THE INVENTION

1. Field of the Invention

The present invention relates to a diamond and an aggregated carbon fiber. Also, the present invention relates to a producing method of a diamond and a producing method of producing an aggregated carbon fiber.

2. Related Background Art

In 1982, it was reported that a diamond crystal can be synthesized from a vapor phase by means of a chemical vapor deposition method (CVD method). Since then, a large number of synthesis methods and apparatuses have been investigated. Most of them require vacuum devices for decomposing and reacting a mixed gas containing a hydrocarbon gas such as methane and hydrogen under a low pressure by using plasma of microwave discharge, high-frequency discharge, arc discharge or the like, so that the configurations of the entire apparatuses are large (see Japanese Patent Application Laid-Open No. H09-249408). Similarly, the synthesis of a carbon nanotube reported in 1991 employs a method such as arc discharge or irradiation with laser, and hence involves a disadvantage in that a production method and a synthesis condition must be severely adjusted and a disadvantage in that an apparatus is expensive.

Investigations into the application of a diamond in the form of a thin film to high-temperature semiconductor devices, electron emitting materials, devices with environmental resistance, and the like have been made. In addition, carbon nanotubes, carbon nanofibers, and carbon fibers are expected to significantly improve the mechanical characteristics and electrical characteristics of hydrogen storage materials for fuel cells, electron emitting materials, and nano-size electronic devices as well as further composite materials of the carbon nanotubes, the carbon nanofibers, and the carbon fibers are combined with plastics, ceramics, rubber, metal, and the like.

However, according to the above method, a vacuum device is needed, and a gas such as hydrogen and plasma are used. Therefore, it is difficult to simply, inexpensively and safely synthesize a diamond crystal, a carbon nanotube or the like.

Exemplified as a conventional method of producing a diamond is a method of producing a diamond by applying high-density energy under an ultrahigh pressure (Japanese Patent Application Laid-Open No. H09-249408). Such a method involves a disadvantage in that the entire apparatus is large and a disadvantage in that the apparatus is expensive.

In addition, (1) a system for exhausting air by means of a vacuum pump to establish an air-free reaction space (Japanese Patent Application Laid-Open No. 2000-095509) or (2) an apparatus for establishing an air-free reaction space by heating a liquid filled in a reaction vessel from the inside by using three glass vessels (Shizuo Fujiwara, “Chemistry IA Revised Edition”, Sanseido Publishing Co., Ltd., 1998, p. 150) is exemplified as a conventional method of producing a carbon nanotube.

However, the system (1) involves a disadvantage in that the entire apparatus is large and a disadvantage in that the apparatus is expensive. The apparatus (2) involves, for example, a disadvantage in that a substance that can be dissolved into powder or a liquid cannot be used as a substrate. Therefore, further simplification and contrivance of an apparatus and a synthesis method have been demanded to aim for industrial production according to the conventional method.

### SUMMARY OF THE INVENTION

The present invention has been made in view of the above circumstances, and an object of the present invention is to provide methods of producing each of a diamond and a carbon fiber such as a carbon nanotube by performing heat treatment under normal pressure in the saturated vapor of a liquid of a carbon source by using only one glass vessel such as a test tube. That is, an object of the present invention is to provide a simple apparatus configuration using a glass vessel without using a vacuum device, a carrier gas such as hydrogen, and plasma, and a simple production method.

The above object is achieved by the present invention described below. That is, according to one aspect of the present invention, there is provided a methods and apparatuses of a diamond and an aggregated carbon fiber by heating the vapor of a liquid of a carbon source to heat treatment in the absence of air, including the following steps (i) and (iii) of, the following steps (ii) and (iii) of, or the following steps (i), (ii) and (iii) of:
(i) heating a liquid containing at least carbon, oxygen and hydrogen as components in a vessel from an outside of the vessel to exhaust air in the vessel by means of the vapor of the liquid;
(ii) introducing a gas into a vessel storing the liquid containing at least carbon, oxygen and hydrogen as components to exhaust air in the vessel; and
(iii) heating the vapor of the liquid containing at least carbon, oxygen and hydrogen as components in an atmosphere of the saturated vapor of the liquid.

According to another aspect of the present invention, there are provided a diamond produced by means of the above methods.

According to another aspect of the present invention, there are provided an aggregated carbon fiber, including stacked carbon fibers having a concentrically hollow shape, wherein the aggregated carbon fiber is produced by the above methods.

The present invention has the features and effects (1) to (5): (1) a reaction is performed under normal pressure without using a carrier gas; (2) a liquid containing at least carbon, oxygen, and hydrogen such as an alcohol is used as a carbon raw material; and thereby (3) a method of easily synthesizing a granular diamond crystal, a diamond film, or a hollow carbon fiber having an amorphous structure and an extremely active surface with high efficiency is obtained; (4) a simple structure, inexpensive and highly safe apparatus of producing them can be assembled because the apparatus can be basically constituted by using only one glass vessel; and (5) an utilizable substrate that can be used can be selected from a significantly expanded range of materials including plate-shaped, granular, fine powdery and pasty solids.

The foregoing is the explanation and illustration of the principle of the present invention, and industrial production is not limited to the foregoing. That is, for example, the glass vessel may be exchanged to a metal vessel equipped with an explosion proof apparatus from the viewpoint of safety, and a vessel volume may be appropriately changed as an example.

The diamond produced by means of the above methods is expected to find applications in electronic emitter materials, high-temperature semiconductor device materials, blue light-emitting device materials, radiation resistant device materials, gas sensor materials, heat sink materials, and electrochemical devices. In addition, a hollow carbon fiber having an extremely large specific surface area and an extremely active surface can find use in a wide variety of applications including electron emitter materials, nano-size transistor materials, molecular wires, secondary battery and capacitor materials, hydrogen storage materials for fuel cells, catalyst materials, biosensor materials, and novel structural materials.

Other features and advantages of the present invention will be apparent from the following description taken in conjunction with the accompanying drawings, in which like reference characters designate the same or similar parts throughout the figures thereof.

### BRIEF DESCRIPTION OF THE DRAWINGS

FIG. 1 is an illustration for explaining a production method according to the present invention;

FIG. 2 is an illustration for explaining a heating method of liquid according to the present invention;

FIG. 3 is an illustration for explaining the method of heating a liquid according to the present invention;

FIG. 4 is an illustration for explaining an exhausting method of air through gas introduction according to the present invention;

FIGS. 5A, 5B, 5C, and 5D are illustrations for explaining the shape and structure of an exhaust pipe according to the present invention;

FIGS. 6A, 6B, 6C, 6D, and 6E are illustrations for explaining the shape and structure of the exhaust pipe according to the present invention;

FIG. 7 is an illustration for explaining a method of enhancing safety according to the present invention; and

FIG. 8 is an illustration for explaining a supplying method of liquid raw material according to the present invention.

### DESCRIPTION OF THE PREFERRED EMBODIMENTS

Preferred embodiments of the present invention will now be described in detail in accordance with the accompanying drawings.

Hereinafter, the present invention will be described in more detail by way of preferred embodiments.

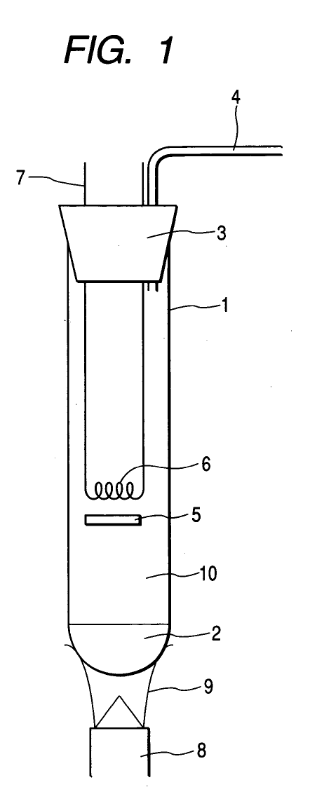

The outlines of the method and apparatus for producing a diamond or a carbon fiber according to the present invention will be described with reference to FIG. 1. A liquid 2 containing at least carbon, oxygen and hydrogen as components is charged into a glass vessel 1 (a test tube is used here). Then, an upper portion of the glass vessel 1 is closed with a rubber stopper 3. A gas exhaust pipe 4 is attached to the rubber stopper 3. A substrate 5 made of Si, Ni or the like is placed at a central portion of the glass vessel 1. A filament 6 made of W is placed at a position of higher by about 1 to 5 mm than that of the substrate 5. The W filament 6 is connected to a metal wire 7, through which a current can flow into the filament.

Examples of the liquid 2 containing carbon, oxygen and hydrogen as components include organic compounds such as an alcohol, an ether, a ketone, an ester, an aldehyde, and a carboxylic acid. A compound having an abundance ratio between the number of carbon atoms and the number of oxygen atoms in the range of 1:2 to 6:1 is suitable, and in particular, a compound having such a ratio in the range of 1:1 to 4:1 is preferable. When the ratio of the number of carbon atoms to the number of oxygen atoms is greater than 6:1, a diamond or carbon fiber is hardly obtained, and an amount of soot to be produced increases. Specific examples of a liquid containing carbon, oxygen and hydrogen as components include methanol, ethanol, propanol, butanol, dimethyl ether, methylethyl ether, formaldehyde, acetaldehyde, acetone, formic acid, acetic acid, and ethyl acetate. However, the present invention is not limited to them.

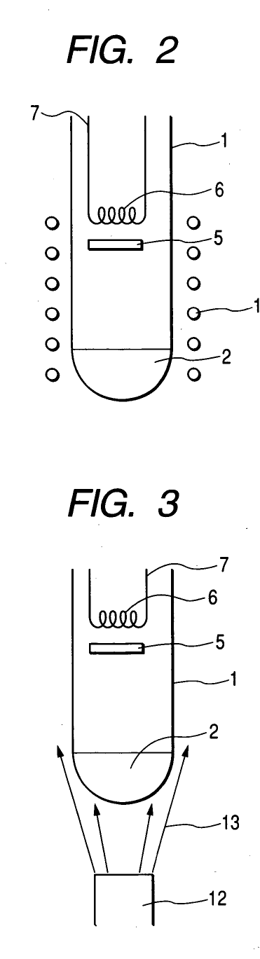

In such a state of the apparatus, the bottom of the glass vessel 1 is heated with a fire 9 of a burner 8 (such as an alcohol lamp or a Bunsen burner) from an outside. There are many methods of heating the bottom of the glass vessel 1 from an outside other than heating with the fire 9. FIG. 2 shows an example in which the bottom is heated with an electric heater 11, and FIG. 3 shows an example in which the bottom is heated with hot air 13 generated by a heated air generator 12, respectively. The liquid 2 is boiled and evaporated by heating. The evaporated vapor is exhausted to the outside of the glass vessel 1 together with the air in the glass vessel 1 through the exhaust pipe 4. Therefore, the inside of the glass vessel 1 is filled with only saturated vapor of the liquid 2 to establish an air-free space 10.

The conventional method involves several problems in terms of creation of the air-free space 10. In contrast, the present invention employs a method involving: heating from the outside and evaporating a small amount (5 to 8 ml) of the liquid 2 of a carbon source placed in the glass vessel 1 in order to exhaust the air in the glass vessel 1; and exhausting the evaporated vapor together with the air in the glass vessel 1 to the outside through the exhaust pipe 4, and hence has a feature that an apparatus configuration, experimental method, and procedure become extremely easy.

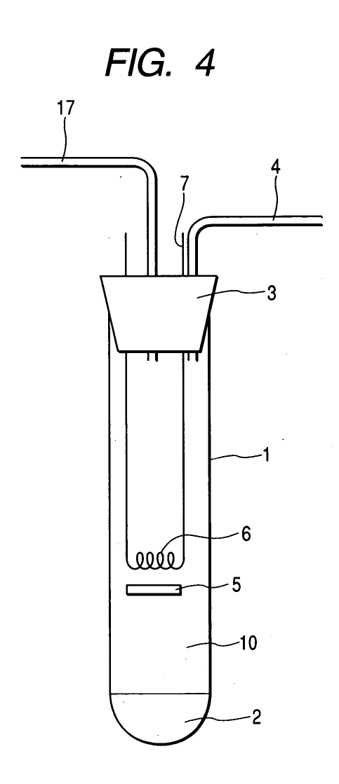

In another examples of the method of exhausting the air in the glass vessel 1, gases such as nitrogen are introduced from the outside into the glass vessel 1 and the air is forcedly exhausted together with these gases. This method is shown in FIG. 4. A gas such as hydrogen, nitrogen, argon, methane or propane is introduced from a gas introducing pipe 17 into the glass vessel 1. After the gas is allowed to flow for several minutes, the air passes through the exhaust pipe 4 to be completely exhausted to the outside, thereby establishing an air-free space 10.

Since the space 10 contains only the saturated vapor of the liquid 2 of a carbon source and is free of air, the W filament 6 can be heated with safety. Then, the W filament 6 is heated to 1,500 to 2,200° C., and at the same time, the fire 9 heating the bottom of the glass vessel 1 is extinguished. In actuality, the burner 8 is removed. The vapor of the liquid 2 as a carbon source, which is heated to 1,500 to 2,200° C., turns into a gas from the vapor to be vigorously released from the exhaust pipe 4. The air from the outside cannot flow into the glass vessel 1 because the pressure of exhausting gas is high. Therefore, the safety of the apparatus is maintained because no inflammation to the liquid 2 as a carbon source occurs and there is no possibility of explosion. The substrate 5 is heated to 300 to 900° C. by heat radiation from the W filament 6. The substrate 5 is made of Si, the substrate temperature is kept at 700 to 900° C., and a reaction is continued for 1 hour or longer, whereby a diamond crystal grows on the Si substrate 5. In addition, the substrate 5 is made of Ni, the substrate temperature is kept at 300 to 700° C., and a reaction is continued for 10 minutes or longer, whereby the aggregated carbon fiber such as a carbon nanotube deposits on the Ni substrate 5.

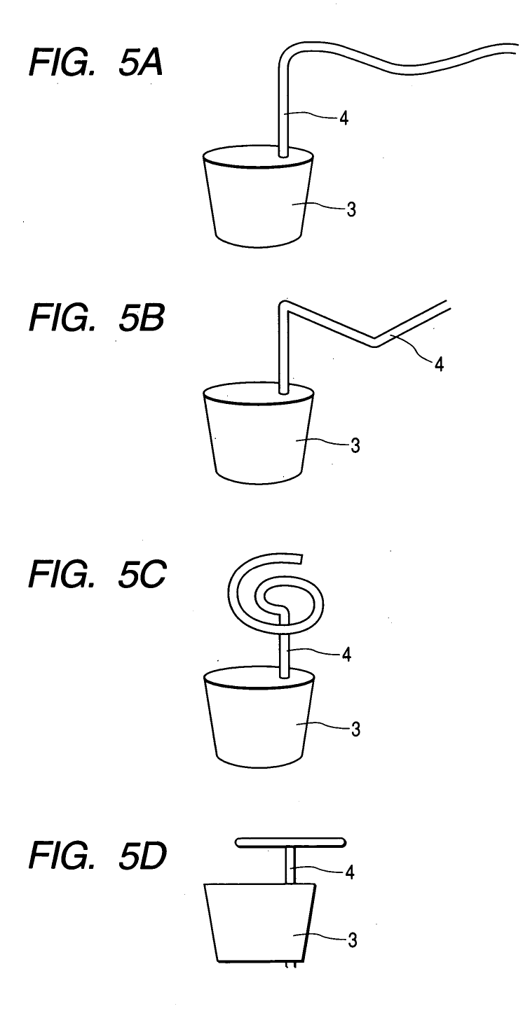

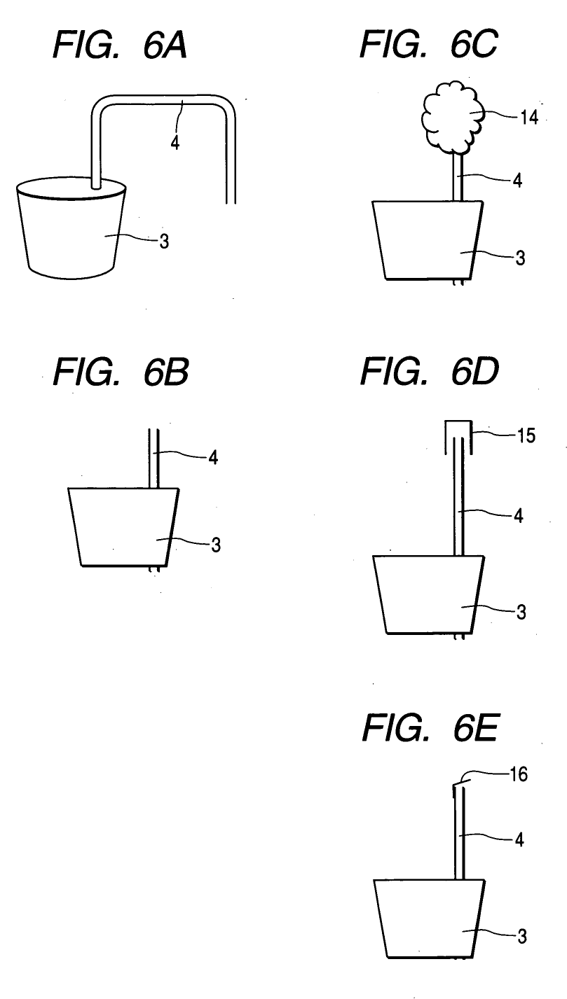

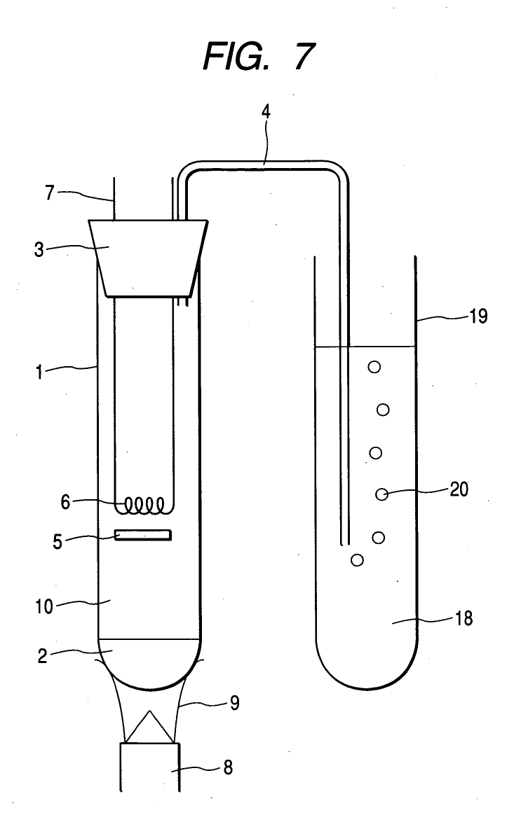

The exhaust pipe 4 of FIG. 1 is typically a thin stainless tube having an external diameter of 1/8 inch and has a typical length of about 200 mm. FIGS. 5A to 5D and FIGS. 6A to 6E each show an contrivance example in which the exhaust pipe 4 is made shorter to increase safety. FIGS. 5A to 5D and FIGS. 6A to 6E show various shapes and structures of the exhaust pipe 4.

FIG. 5A shows the exhaust pipe 4 with its linear portion slightly sagged downward to have a shorter length of 150 mm. FIG. 5B shows the exhaust pipe 4 bent with some degree of angle. The pipe of FIG. 5B is basically the same as the pipe of FIG. 5A. FIG. 5C shows the exhaust pipe 4 having an eddy shape, which can be placed in a space above the glass vessel 1 to facilitate an experimental operation. Although the exhaust pipe 4 having an eddy shape has a length in the range from 150 to 200 mm, the diameter of the eddy is equal to that of the rubber stopper, that is, about 30 mm. FIG. 5D is a side view of FIG. 5C.

FIG. 6A shows an exhaust pipe 4 having an exhaust port directed downward as shown in the figure and having a U shape as the entire shape. A gas is exhausted downward to facilitate an experimental operation. The exhaust pipe 4 has a length in the range from 150 to 200 mm. FIG. 6B shows an exhaust pipe 4 having a linear shape and a thinner internal diameter of 1/16 inch. Because the diameter is made thinner, the exhaust pressure of a gas increases and inflow of air does not occur. The exhaust pipe 4 has a length of 100 mm. Although it is difficult to attach the exhaust pipe 4 to the rubber stopper 3 because the pipe is made thinner, a simple structure is established, and hence experimental operability increases. FIG. 6C shows an exhaust pipe 4 using a stainless pipe having an internal diameter of 1/8 inch which is made linear and directed upward from the rubber stopper 3. When the length is reduced to 50 to 100 mm, the inflow of air can be prevented by covering a tip of the exhaust pipe 4 with a fibrous substance 14 (cotton is used here). That is, the fibrous substance is found to serve as a check valve. Similarly to FIG. 6C, FIG. 6D shows a state where a lightweight and small cup 15 (a plastic cup is used here) is mounted on the tip of the exhaust pipe 4. The cup serves as a check valve. The pipe has a length in the range from 50 to 100 mm. FIG. 6E shows a state where a lightweight check valve 16 made of plastic or the like (a plastic check valve is used here) is mounted on the tip of the exhaust pipe 4. The pipe has a length in the range from 50 to 100 mm. As described above, an apparatus configuration can be simplified by giving contrivance to the exhaust pipe 4 in various ways.

As described above, the air from the outside atmosphere does not flow into the glass vessel 1 because the exhaust pressure of a gas through the exhaust pipe 4 is high. FIG. 7 shows a contrivance example of an apparatus with enhanced safety. In an apparatus having a basic structure shown in FIG. 1, the exhaust pipe 4 is placed in a transparent vessel 19 (a glass vessel or a plastic vessel is used here) containing water 18. The experimental procedure is as described in DESCRIPTION OF THE PREFERRED EMBODIMENTS. Once vapor or a gas starts to be exhausted from the inside of the glass vessel 1, bubbles 20 of a gas are released from the tip of the exhaust pipe 4 in the water 18. As the reaction proceeds, the amount or number of bubbles 20 becomes constant and this state continues till the completion of the experiment. The air from the outside atmosphere never flows into the vessel from the exhaust pipe 4 because the air stops at the water surface. Therefore, no inflammation to the liquid 2 as a carbon source in the glass vessel 1 occurs, and there is no possibility of explosion. Therefore, the safety of the apparatus can be extremely high.

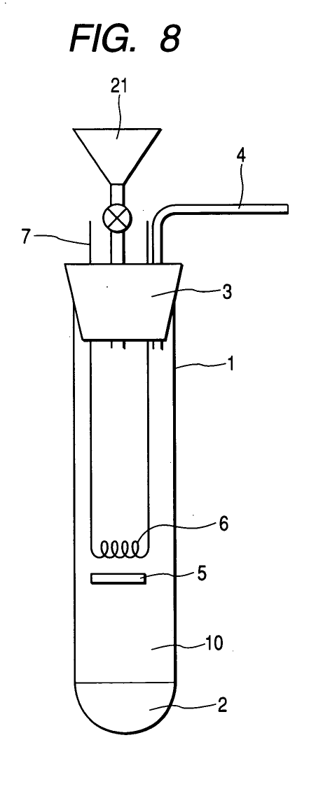

The vapor of the liquid 2 as a carbon source is heated by heat of the W filament 6 to be decomposed into carbon-based excited species (such as C, CH, and C₂) and carbon-based gases (such as CH₄, C₂H₂, and CO). A part of those excited species and carbon-based gases is expected to deposit as a diamond crystal or a carbon fiber. As the reaction proceeds, the liquid 2 as a raw material is consumed. FIG. 8 shows a contrivance example for replenishing a raw material. The consumed liquid 2 is supplied from a funnel 21 attached to the rubber stopper 3 placed at the upper portion of the glass vessel 1, and a quantity of liquid is always kept constant. The remaining amount of the liquid 2 as a carbon source is desirably such that the quantity of liquid is below the substrate 5. In other words, the remaining amount is suitably 30% or less of the glass vessel capacity 1.

Results of crystallographic characterization of the resultant deposit are shown. When a reaction time is 1 hour or shorter, a diamond deposits as a granular crystal. When the reaction time is 1 hour or longer, or if possible, 2 to 3 hours, the diamond deposits as a film-shaped diamond. When the surface morphology is observed with a field emission-type scanning electron microscope (FE-type SEM), a film having a diameter of several microns surrounded by a triangle (111 plane) and a quadrangle (100 plane) is observed. Furthermore, characterization by means of laser Raman spectroscopy identified the resultant film-shaped substance as a diamond because the substance has a sharp peak at 1,333 cm⁻¹ as in a natural cubic diamond.

In addition, when the resultant aggregated carbon fiber is observed with a FE-type SEM, a large number of rope-shaped carbon fibers are observed. The diameter of each of those carbon fibers is in the range from about 10 nm to submicrons. Observation with a transmission electron microscope (TEM) shows that there is a carbon nanotube having a diameter of 75 nm and an internal diameter of 20 nm (hollow nano-size carbon fiber). Further, it is also shown that those carbon fibers have an amorphous structure. The carbon fibers are considerably different from the crystalline carbon fibers conventionally reported in this point. This difference is probably because a temperature for producing them is as low as 300 to 700° C.

A substrate to be used as the substrate 5 suitable for the growth of a diamond preferably contains at least one element selected from Si, Mo, W, Cu, Ta, Ti, Pt, Ir, Zn, and Al. A substrate made of each of the carbides such as SiC, Mo₂C, WC, TaC, and TiC is also preferable. On the other hand, a substrate to be used as the substrate 5 suitable for the growth of a carbon fiber preferably contains at least one element selected from Ni, Fe, Co, Pd, Pt, Ru, Rh, Ti, and Cu, and the substance may have various shapes such as plate-like, granular, fine powdery, and pasty shapes. A substrate made of Ni, Fe, or Co is most desirable for the growth of a carbon fiber. A substrate made of the sulfides such as FeS or NiS is also preferable.

Application and use of a metal complex having a Group-X metal such as Ni, Pd, or Pt or having a metal such as Fe or Ru onto a substrate increase the production yield of a carbon fiber. Specific examples of the metal complex include platinum acetylacetonate, nickel acetylacetonate, palladium acetylacetonate, cobalt acetylacetonate, and iron acetylacetonate. However, the present invention is not limited to them.

In addition, the liquid 2 as a carbon source may be mixed with water to be used. The effect of the present invention is confirmed even when the liquid 2 as a carbon source is added with 1 to 50% by volume of water. For the efficacy, the water content is desirably 20% by volume or less for synthesis of a diamond crystal, while the water content is desirably 10% by volume or less for synthesis of a carbon fiber.

The dispersion or dissolution of the metal complex compound into the liquid 2 as a carbon source increases the growth rate of a hollow carbon fiber. The concentration of the compound is 0.0005 to 1.0 g, desirably 0.001 to 0.5 g with respect to 100 ml of the liquid.

The dispersion or dissolution of a sulfur-containing compound such as thiol, thioether, thiocarbonyl, carbon sulfide, hydrogen sulfide, a sulfuric acid compound, or an aromatic thio compound into the liquid 2 as a carbon source also increases the growth rate of a hollow carbon fiber.

The sulfur-containing solution desirably has a composition with an element abundance ratio between carbon and sulfur in the range of preferably 100:1 to 1,000,000:1, particularly preferably 300:1 to 100,000:1.

As described above, the present invention relates to specific methods of producing a diamond and a hollow carbon fiber, and a simple synthesis apparatuses constituted by a glass vessel. In addition, the present invention is, for example, characterized in that: (1) the apparatuses are basically constituted by one glass vessel; (2) no carrier gas is used; (3) no vacuum device is needed because a reaction is performed under normal pressure; (4) the safety operation at experiment increases because the amount of a liquid can be reduced from that of the conventional method by one tenth to one several tenth; and (5) a substrate can be selected from a significantly expanded range including plate-shaped, granular, fine powdery, and pasty solids.

Hereinafter, the present invention will be described more specifically by way of examples.

### EXAMPLE 1

The capacity of the glass vessel shown in FIG. 1 having an external diameter of 30 mm and a length of 200 mm is 120 ml. When 5 ml of methanol were charged into the vessel, methanol accumulated at the bottom inside the glass vessel. When an upper portion of the glass vessel was capped with a rubber stopper, air remained in the glass vessel in this state. A Si substrate having a size of 5×5×0.2 mm was placed at a position 1 mm below the W filament. The bottom of the glass vessel was heated with fire of an alcohol lamp from an outside. Methanol was boiled and evaporated by heating. The evaporated methanol was exhausted to the outside of the glass vessel together with the air in the glass vessel through the stainless exhaust pipe. When heating was continued for 3 minutes, the air was completely exhausted. Therefore, a space filled with only saturated vapor of methanol was established in the glass vessel. The space of evaporated methanol vapor accounted for about 95% of the glass vessel. The methanol as a carbon raw material continued to evaporate from the bottom of the reaction vessel, and served as a raw material for synthesizing a diamond. When the W filament was heated to 2,000° C., the substrate temperature of the Si kept about 800° C. Continuing the synthesis for 1 hour resulted in the deposition of a granular diamond crystal on the Si substrate.

Observation with a FE-type SEM revealed that each granular crystals each having a diameter in the range from 2 to 5 μm deposited. Furthermore, characterization by means of laser Raman spectroscopy identified the resultant crystal as a diamond because the resultant crystal had a sharp peak at 1,333 cm⁻¹ as in a natural cubic diamond. It was also found that the crystal contained an amorphous carbon component because the crystal had a broad peak nearby 1,550 cm⁻¹. Evaluation of the quality of the crystal by means of an X-ray diffraction method revealed that the crystal was a polycrystalline diamond.

### EXAMPLE 2

The apparatus shown in Example 1 was used. A reaction was performed under the same conditions as those of Example 1 except that a Si substrate surface polished with a fine diamond powder was used, and a reaction time was changed to 4 hours. As a result, a film-shaped diamond was obtained. A film thickness and a growth rate were measured by means of a scanning electron microscope (SEM). An average film thickness was 10 μm and the growth rate was about 2.5 μm/h. The result confirmed that polishing the Si substrate surface had an increased effect on the growth rate.

### EXAMPLE 3

The apparatus shown in Example 1 was used, and a film-shaped diamond grew under the same conditions as those of Example 2 except that the Si substrate was changed to a Mo plate, a W plate, a Ta plate, a SiC plate, a Mo₂C plate, and a TaC plate, the temperature of the W filament was increased to 2,200° C., and a reaction time was set to 4 hours. As a result, the increase of the heating temperature by 200° C. increased the growth rate to 3 μm/h.

### EXAMPLE 4

Deposition of a diamond crystal was performed by using the apparatus shown in FIG. 2. The experimental procedure was substantially the same as that of Example 1 except that an electric heater was used for external heating. A current was passed through the electric heater wound around the bottom of the glass vessel to heat the bottom to about 300° C. Methanol at the bottom of the glass vessel evaporated, and the air was completely exhausted to the outside of the vessel in 2 minutes. After that, a reaction was performed under the same experimental conditions as those of Example 1. As a result, a granular diamond deposited on the Si substrate.

### EXAMPLE 5

Deposition of a diamond crystal was performed by using the apparatus shown in FIG. 3. The experimental procedure was substantially the same as that of Example 1 except that hot air was used for external heating. A hot air supply used here was a commercially available drier with an electric power of 800 W. When a hot air (having a temperature of about 200° C.) was blown toward the bottom of the glass vessel, methanol evaporated, and the air was completely exhausted to the outside of the vessel in 3 minutes. After that, a reaction was performed under the same experimental conditions as those of Example 1. As a result, a granular diamond deposited on the Si substrate.

### EXAMPLE 6

5 ml of methanol as a carbon source were charged into the bottom of a vessel. The configuration of the apparatus shown in FIG. 4 was employed, and deposition of a diamond crystal was performed. When a hydrogen gas was continuously allowed to flow from the gas introducing pipe 17 at a rate of 100 ml/min for 5 minutes, the air in the glass vessel was completely exhausted to the outside of the vessel. Introduction of the hydrogen gas is intended to exhaust the air, and essentially does not adversely affect the diamond synthesis. The flow of the hydrogen gas may be continued or stopped. In this example, the flow of the hydrogen gas was stopped, and, similarly to Example 1, the W filament was heated to 2,000° C., and a reaction was continued for 1 hour. As a result, a granular diamond crystal deposited on the Si substrate.

### EXAMPLE 7

A raw material for the liquid as a carbon source was methanol added with 12.5% by volume of ethanol. A reaction was performed by adopting the apparatus and experimental procedure shown in Example 1, a reaction time of 4 hours, and a Si substrate with a polished surface. As a result, a film-shaped diamond was obtained. A carbon source concentration increased owing to the mixing of ethanol, whereby the growth rate increased to about 4 μm/h.

### EXAMPLE 8

The same apparatus as that of Example 1 was used, but the carbon source was changed to ethanol, the substrate was changed to Ni substrate, and a gap between the W filament and the substrate was set to 5 mm. When the filament temperature was set to 2,000° C., the Ni substrate temperature kept on 500° C. A reaction was continued for 15 minutes. As a result, black deposits grew on the Ni substrate. Observation by means of a FE-type SEM revealed that the deposits were carbon fibers of a nano-size to submicron-size. Characterization by means of a TEM was performed in order to observe the inside of each of the fibers. The characterization revealed that the carbon fibers were typically carbon nanotubes (hollow carbon fibers) each having a diameter of 80 nm and an internal diameter of 30 nm. Observation by means of a TEM also revealed that those carbon fibers each had an amorphous structure.

### EXAMPLE 9

A reaction was performed under the same conditions as those of Example 8 except that the Ni substrate was changed to a substance made of submicron-size Ni fine powder. The Ni fine powder is expected to increase the growth rate because it has an extremely large surface area as compared to a Ni plate. Deposition of carbon fibers was observed even with a reaction time of about 3 to 5 minutes. The resultant carbon fibers were hollow, and the dimensions and structure of the fibers were substantially the same as those of Example 8. The above results showed that the use of a substance with a large surface area increases a growth rate.

### EXAMPLE 10

By performing RF sputtering of a metal Ni, a nano-size Ni catalyst nucleus was formed on a Si substrate. By using the substrate and the apparatus shown in Example 1, an experiment was performed under the same experimental conditions as those of Example 8. Observation by means of a FE-type SEM and a TEM revealed that very thin carbon fibers deposited as a result of the experiment. The fibers were carbon nanotubes each having an external diameter of 15 nm and an internal diameter of 10 nm as typical numerical values, and a part of the fibers had graphite structures and were crystallized.

### EXAMPLE 11

5 ml of methanol as a carbon source were charged into the bottom of a vessel. The configuration of the apparatus shown in FIG. 4 was employed, and deposition of carbon fibers was performed. When a methane gas was continuously allowed to flow from the gas introducing pipe 17 at a rate of 200 ml/min for 3 minutes, the air in the glass vessel was completely exhausted to the outside of the vessel. Introduction of the methane gas is intended to exhaust the air, but methane serves as a carbon source together with methanol because methane contains carbon. In this example, the methane gas was continuously allowed to flow at a rate of 10 ml/min, and, similarly to Example 8, the W filament was heated to 2,000° C., and a reaction was continued for 15 minutes. As a result, an aggregated hollow carbon fiber of a nano-size to submicron-size deposited on the Ni substrate.

### EXAMPLE 12

A reaction was performed under the same conditions as those of Example 8 except that the temperature of the W filament was 1,700° C. As a result, a small amount of hollow amorphous carbon fibers were obtained.

### EXAMPLE 13

A reaction was performed under the same conditions as those of Example 8 except that ethanol as a raw material was changed to a methanol solution, and the substrate temperature was changed to 400° C. As a result, the obtained carbon fibers were found to have a hollow shape. Furthermore, observation by means of a FE-type SEM revealed that the surface of each fiber had a large ragged structure.

### EXAMPLE 14

A reaction was performed under the same conditions as those of Example 8 except that ethanol as a raw material was changed to a mixed liquid of 30 volume % of ethanol and 70 volume % of propanol. Although the amount of soot increased, carbon fibers were obtained. Observation by means of a SEM and a TEM revealed that each of the fibers had a hollow shape.

### EXAMPLE 15

The Si substrate 5 shown in FIG. 1 applied to a solution prepared by adding platinum acetylacetonate to ethanol at a ratio of 0.1 g of platinum acetylacetonate to about 100 ml of ethanol was used. The other conditions were the same as those of Example 8. Heating the W filament caused not only ethanol vapor but also fine powder of platinum acetylacetonate to start drifting in the space 10. Although the experimental conditions were the same as those of Example 8, the amount of carbon fibers deposited on the Si substrate was 2 to 5 times as large as that of Example 8 for a synthesis time of about 5 minutes. In addition, observation by means of a FE-type SEM and a TEM revealed that each of the obtained carbon fibers had a hollow shape.

### EXAMPLE 16

A reaction was performed under the same conditions as those of Example 8 except that 85 ml of ethanol and 15 ml of water (the addition amount of water was 15 volume % by volume) were used as raw materials (carbon sources). Observation by means of a SEM and a TEM confirmed that hollow carbon fibers can be synthesized. Addition of water reduced the amount of hollow carbon fibers and reduced the external and internal diameters of each carbon fiber. However, a large amount of soot was observed to be removed. Observation by means of a SEM showed that hollow carbon fibers were synthesized to cover the entire surface of the Ni substrate.

### EXAMPLE 17

The apparatus shown in FIG. 1 was used, and a liquid obtained by adding carbon disulfide (CS₂) as a carbon source to methanol at a volume concentration of 0.01% was charged into the glass vessel. Then, a reaction was performed under the same conditions as those of Example 8 except that the W filament temperature was set to 2,000° C., the Ni substrate was used, the substrate temperature was 500° C., and the reaction time was 15 minutes. Observation by means of a FE-type SEM revealed that carbon fibers of a submicron size to micron size that is thicker than typical ones grew on the substrate.

### EXAMPLE 18

A reaction was performed under the same conditions as those of Example 8 except that ethanol as a raw material was changed to dimethyl ether. As a result, hollow carbon fibers were obtained.

### EXAMPLE 19

A reaction was performed under the same conditions as those of Example 8 except that ethanol as a carbon source was changed to acetone. As a result, hollow carbon fibers were obtained.

A diamond obtained according to the production method of the present invention can use in applications including semiconductor device materials, electron emitting materials, materials for environmental resistance, and sensor materials when the diamond is formed into a thin film. Possible applications of carbon nanotubes, carbon nanofibers and carbon fibers include conductive fillers for conductive resins and for rubber materials because the carbon nanotubes, the carbon nanofibers, and the carbon fibers have good compatibility with resin materials. Those conductive resins and rubber materials can be used, for example, for electrophotographic functional components such as charging rollers, transferring rollers, transferring belts, and intermediate transfer parts. In addition, the carbon nanotubes, carbon nanofibers and carbon fibers can be used for catalyst carriers for fuel cells, hydrogen storage materials and the like because the surface of each fiber has high activity and low resistance.

The present invention is not limited to the above embodiments and various changes and modifications can be made within the spirit and scope of the present invention. Therefore to apprise the public of the scope of the present invention, the following claims are made.

This application claims priority from Japanese Patent Application No. 2004-089533 filed on Mar. 25, 2004, which is hereby incorporated by reference herein.

1. A method of producing a diamond by subjecting a vapor of a liquid of a carbon source to heat treatment in absence of air, comprising the following steps (i) and (iii) of, the following steps (ii) and (iii) of, or the following steps (i), (ii) and (iii) of:
(i) heating a liquid containing at least carbon, oxygen, and hydrogen as components in a vessel from an outside of the vessel to exhaust air in the vessel by a vapor of the liquid;
(ii) introducing a gas into the vessel storing the liquid containing at least carbon, oxygen, and hydrogen as components to exhaust air in the vessel; and
(iii) heating the vapor of the liquid containing at least carbon, oxygen, and hydrogen as components in an atmosphere of a saturated vapor of the liquid.

2. A method of producing an aggregated carbon fiber by subjecting a vapor of a liquid of a carbon source to heat treatment in absence of air, comprising the following steps (i) and (iii) of, the following steps (ii) and (iii) of, or the following steps (i), (ii) and (iii) of:
(i) heating a liquid containing at least carbon, oxygen, and hydrogen as components in a vessel from an outside of the vessel to exhaust air in the vessel by a vapor of the liquid;
(ii) introducing a gas into the vessel storing the liquid containing at least carbon, oxygen, and hydrogen as components to exhaust air in the vessel; and
(iii) heating the vapor of the liquid containing at least carbon, oxygen, and hydrogen as components in an atmosphere of a saturated vapor of the liquid.

3. A method of producing an aggregated carbon fiber according to claim 2, wherein the liquid of the carbon source and a reaction portion for synthesizing a carbon fiber are placed in one vessel.

4. A method of producing an aggregated carbon fiber according to claim 2, wherein the steps (i) to (iii) are performed in one vessel.

5. A method of producing an aggregated carbon fiber according to claim 2, wherein an exhaust pipe for exhausting air is open to an atmosphere.

6. A method of producing an aggregated carbon fiber according to claim 2, wherein an exhaust pipe for exhausting air is immersed into the liquid.

7. A method of producing an aggregated carbon fiber according to claim 2, wherein the liquid is replenished from a device placed on an upper portion of the vessel.

8. A method of producing an aggregated carbon fiber according to claim 2, wherein a ratio in a number of carbon atoms constituting the liquid to oxygen atoms constituting the liquid is in a range of 1:2 to 6:1.

9. A method of producing an aggregated carbon fiber according to claim 2, wherein the liquid contains at least one selected from the group consisting of an alcohol, an ether, a ketone, an ester, an aldehyde and a carboxylic acid compound.

10. A method of producing an aggregated carbon fiber according to claim 2, wherein the liquid contains at least one selected from the group consisting of methanol, ethanol, propanol and butanol.

11. A method of producing an aggregated carbon fiber according to claim 2, wherein the liquid contains dimethyl ether or methylethyl ether.

12. A method of producing an aggregated carbon fiber according to claim 2, wherein the liquid contains formaldehyde or acetaldehyde.

13. A method of producing an aggregated carbon fiber according to claim 2, wherein the liquid contains at least one selected from the group consisting of formic acid, acetic acid and ethyl acetate.

14. A method of producing an aggregated carbon fiber according to claim 2, wherein the liquid used in the steps (i) to (iii) contains 1 to 50 volumw % of water.

15. A method of producing a aggregated carbon fiber according to claim 2, wherein the liquid used in the steps (i) to (iii) further contains a metal complex compound.

16. A method of producing an aggregated carbon fiber n according to claim 15, wherein a main metal of the metal complex compound is at least one element selected from the group consisting of platinum, palladium, nickel, iron, cobalt, rhodium and ruthenium.

17. A method of producing an aggregated carbon fiber according to claim 2, wherein the liquid used in the steps (i) to (iii) is a liquid containing carbon, oxygen, hydrogen and sulfur as components.

18. A method of producing an aggregated carbon fiber according to claim 2, wherein the heating of the liquid in the step (i) is performed by using a heat source outside the vessel.

19. A method of producing an aggregated carbon fiber according to claim 2, wherein the gas used in the step (ii) is at least one selected from the groups consisting of hydrogen, nitrogen, argon, xenon, helium and a hydrocarbon.

20. A method of producing an aggregated carbon fiber according to claim 19, wherein the hydrocarbon is at least one selected from the group consisting of methane, ethane, propane, butane, ethylene, acetylene, propylene, butylene, propine, butyne and butadiene.

21. A method of producing an aggregated carbon fiber according to claim 2, wherein the heating of the vapor of the liquid in the step (iii) is performed by using a filament placed in the atmosphere of the saturated vapor of the liquid.

22. A method of producing an aggregated carbon fiber according to claim 21, further comprising the step of heating the filament to 1,500 to 2,500° C. in the step (iii).

23. A method of producing an aggregated carbon fiber according to claim 2, wherein the step (iii) includes the step of forming the aggregated carbon fiber on a substrate placed in the atmosphere of the saturated vapor of the liquid.

24. A method of producing an aggregated carbon fiber according to claim 23, wherein the substrate contains at least one element selected from the group consisting of nickel, platinum, ruthenium, rhodium, iron, titanium, palladium, copper, tungsten, silicon, tantalum, iridium, zinc, aluminum, cobalt and molybdenum.

25. A method of producing an aggregated carbon fiber according to claim 24, wherein the substrate contains nickel.

26. A diamond produced by means of the method according to claim 1.

27. A diamond according to claim 26, wherein the diamond is a crystalline grains having a grain size in a range from 1 to 200 nm.

28. An aggregated carbon fiber comprising stacked carbon fibers each having a concentrically hollow shape, wherein the aggregated carbon fiber is produced by the method according to claim 2.

29. An aggregated carbon fiber according to claim 28, wherein the carbon fiber is a body formed by stacking amorphous cluster having a diameter in a range from 1 to 5,000 nm.
